(19) United States
(12) Patent Application Publication
(10) Pub. No.: US 2025/0118659 A1
(43) Pub. Date: Apr. 10, 2025

(54) ELECTRONIC COMPONENT

(71) Applicant: Murata Manufacturing Co., Ltd., Nagaokakyo-shi (JP)

(72) Inventors: Takaaki MIZUNO, Nagaokakyo-shi (JP); Toshiyuki NAKAISO, Nagaokakyo-shi (JP); Kenji TOYOSHIMA, Nagaokakyo-shi (JP); Yoshimasa YOSHIOKA, Nagaokakyo-shi (JP)

(21) Appl. No.: 18/987,891

(22) Filed: Dec. 19, 2024

Related U.S. Application Data
(63) Continuation of application No. PCT/JP2023/023730, filed on Jun. 27, 2023.

(30) Foreign Application Priority Data
Jun. 30, 2022 (JP) 2022-105968

(51) Int. Cl. H01L 23/522; H01L 21/768; H10D 1/20; H10D 1/68

(52) U.S. Cl. CPC H01L 23/5227; H01L 21/768; H01L 23/5223; H01L 23/5228; H10D 1/20; H10D 1/692

(57) ABSTRACT

An electronic component is provided that includes a substrate, an insulator layer, an inductor in the insulator layer, planar conductors extending along the substrate, and connecting conductors electrically connected to the planar conductors. The inductor includes surface direction conductors and a plurality of inductor via conductors that connect the surface direction conductors. A direction of a current flowing through an inductor via conductor among the plurality of inductor via conductors configuring a portion of a helical coil having a winding axis along the surface of the substrate, the inductor via conductor being adjacent to the connecting conductors, and a direction of a current flowing through the connecting conductors are opposite to each other.

### CROSS REFERENCE TO RELATED APPLICATIONS

The present application is a continuation of International Application No. PCT/JP2023/023730, filed Jun. 27, 2023, which claims priority to Japanese Patent Application No. 2022-105968, filed Jun. 30, 2022, the entire contents of each of which are hereby incorporated by reference in their entirety.

### TECHNICAL FIELD

The present disclosure relates to an electronic component including a helical coil inductor and a planar conductor.

### BACKGROUND

A coil component in which a helical coil is provided at a substrate is configured as an inductor.

Japanese Unexamined Patent Application Publication No. 2004-103756 (hereinafter the “'756 Application”) discloses a coil component that is produced by cutting a core substrate into chips, the core substrate having a plurality of beltlike conductors on both the top and reverse surfaces and insulating layers covering the beltlike conductors. Specifically, this coil component, on both the right and left side surfaces of a rectangular parallelepiped insulator of which the material is the core substrate, has a plurality of side conductors composed of the beltlike conductors, and an insulating layer covering the side conductors. In addition, the side conductors, and bridging conductors each connecting the side conductors on the top and bottom surfaces of the insulator configure a rectangle helical coil.

Moreover, Japanese Unexamined Patent Application Publication No. 2021-197454 (hereinafter the “'454 Application”) discloses a wiring substrate that includes a first insulating layer including no core material, a first conductor layer and a second conductor layer provided so as to face each other via the first insulating layer, and a plurality of via conductors passing through the first insulating layer and connecting the first conductor layer and the second conductor layer. The first conductor layer and the second conductor layer are adjacent through the first insulating layer. In addition, a magnetic material having a predetermined shape is embedded in the first insulating layer so as not to be in contact with any of the first conductor layer, the second conductor layer, and the plurality of via conductors. Wiring patterns contained in each of the first conductor layer and the second conductor layer, and the plurality of via conductors configure a coil around the magnetic material. The coil extends in a direction that intersects a stacked direction of the wiring substrate.

When an inductor is configured on a conductive substrate, such as a doped silicon substrate, it is effective to place an aperture direction of a magnetic flux of a helical coil parallel to the substrate so as not to deteriorate the Q value. In other words, the magnetic flux generated by the coil does not penetrate the substrate, which is able to reduce loss due to an eddy current. However, when the inductor is made into a component and is placed on a circuit board, together with an element, such as a conductive material or another electronic component, when an LC composite component, such as an LC filter or an impedance matching circuit, is provided by combining the inductor with a capacitor, problems to be described below arise.

When a helical coil is produced like the coil component disclosed in the '756 Application and the '454 Application, the helical coil is provided along a surface parallel to a surface of the substrate. However, when other electronic components are adjacently provided near an aperture of the helical coil, an eddy current due to a magnetic field of the helical coil is generated at a conductor portion of this electronic component, which deteriorates the electrical characteristics of the composite component.

In addition, when an LC composite component, such as an LC filter or an impedance matching circuit, is provided by combining the inductor with a capacitor, problems described below arise.

When a helical coil is produced like the coil component disclosed in the '756 Application and the '454 Application, either the top surface or the bottom surface parallel to the surface of the substrate is a start end or a termination end. However, when internal wiring electrically connected to a terminal or another element is provided near the aperture of the helical coil, the eddy current due to the magnetic field is generated in the internal wiring, which deteriorates the electrical characteristics of the composite component.

### SUMMARY OF THE INVENTION

In view of the foregoing, exemplary embodiments of the present disclosure, in an electronic component having a helical coil in which an aperture direction of a magnetic flux of the helical coil is placed parallel to a substrate, provide an electronic component configured to reduce a size of an electronic device on which the electronic component having the helical coil and other elements are mounted even when being mounted together with an element, such as another conductive material or an electronic component.

In addition, exemplary embodiments of the present disclosure are directed to provide a small electronic component including internal wiring together with an inductor having a predetermined inductance.

An electronic component as one example of the present disclosure includes a substrate, an insulator layer on at least a portion of a surface of the substrate, an inductor in the insulator layer, one or more planar conductors at the substrate or in the insulator layer and extending along the substrate, and one or more connecting conductors electrically connected to the one or more planar conductors. In this aspect, the inductor includes a plurality of surface direction conductors each extending in a plurality of layers along the surface of the substrate, and a plurality of inductor via conductors to connect the plurality of surface direction conductors extending in different layers among the plurality of layers. The inductor is provided by a helical coil having a winding axis along the surface of the substrate, and a direction of a current flowing through an inductor via conductor among the plurality of inductor via conductors that is adjacent to the one or more connecting conductors and a direction of a current flowing through the one or more connecting conductors are opposite to each other.

According to the exemplary aspects of the present disclosure, in an electronic component having a helical coil in which an aperture direction of a magnetic flux of the helical coil is placed parallel to a substrate, an electronic component is provided that is configured to reduce a size of an electronic device on which the electronic component having the helical coil and other elements are mounted when being mounted together with an element such as another conductive material or an electronic component. Moreover, a small electronic component including internal wiring together with an inductor having a predetermined inductance is also provided.

### BRIEF DESCRIPTION OF DRAWINGS

FIG. 1 shows a structure of an electronic component 101 according to a first exemplary embodiment.

FIG. 2 is an equivalent circuit diagram of the electronic component 101.

FIG. 3A is a plan view showing a positional relationship between the electronic component 101 and a different member 201 adjacent to the electronic component 101.

FIG. 3B is a plan view showing a positional relationship between an electronic component 301 as a comparative example and a member 201 such as a different electronic component adjacent to the electronic component 301.

FIG. 4A is a plan view of an electronic component 111. FIG. 4B is a plan view of an electronic component 311 as a comparative example, the electronic component 311 including a helical coil together with a different member 21 in the electronic component.

FIG. 5 shows a structure of an electronic component 102 according to a second exemplary embodiment.

FIG. 6 is a cross-sectional view in a state in which a planar conductor 3 is provided.

FIG. 7 is a cross-sectional view in a state in which a dielectric layer 11 is provided.

FIG. 8 is a cross-sectional view in a state in which a planar conductor 4 is provided.

FIG. 9 is a cross-sectional view in a state in which an insulator layer 2 is provided.

FIG. 10 is a cross-sectional view in a state in which a surface direction conductor 5B and a planar conductor connecting conductor 7B are provided.

FIG. 11 is a cross-sectional view in a state in which an inductor via conductor 6 and a planar conductor connecting conductor 7C are provided.

FIG. 12 is a cross-sectional view in a state in which a surface direction conductor 5A and terminal electrodes 9A and 9B are provided.

FIG. 13 is a cross-sectional view in a state in which terminal electrodes 10A and 10B are provided.

FIG. 14 shows a structure of an electronic component 103 according to a third exemplary embodiment.

FIG. 15 is a cross-sectional view in a state in which a substrate conduction electrode 12, the dielectric layer 11, the planar conductor 4, and the like are provided.

FIG. 16 is a cross-sectional view in a state in which the surface direction conductor 5B and the planar conductor connecting conductor 7B are provided.

FIG. 17 is a cross-sectional view in a state in which the inductor via conductor 6 and the planar conductor connecting conductor 7C are provided.

FIG. 18 is a cross-sectional view in a state in which the surface direction conductor 5A and the terminal electrodes 9A and 9B are provided.

FIG. 19 is a cross-sectional view in a state in which the terminal electrodes 10A and 10B are provided.

FIG. 20 shows a structure of an electronic component 104 according to a fourth exemplary embodiment.

### DETAILED DESCRIPTION

Hereinafter, a plurality of exemplary embodiments will be described with reference to the attached drawings and several specific examples. In the drawings, components and elements assigned with the same reference numerals or symbols will represent identical components and elements. While an exemplary embodiment is divided and described into a plurality of exemplary aspects for the sake of convenience in consideration of ease of description or understanding of main points, elements described in different exemplary embodiments can be partially replaced or combined with each other as would be appreciated to one skilled in the art. In the second and subsequent exemplary embodiments, a description of features common to the first exemplary embodiment will be omitted, and only different features will be described. In particular, the the same same advantageous functions and effects by configurations will not be described one by one for each exemplary embodiment.

### First Exemplary Embodiment

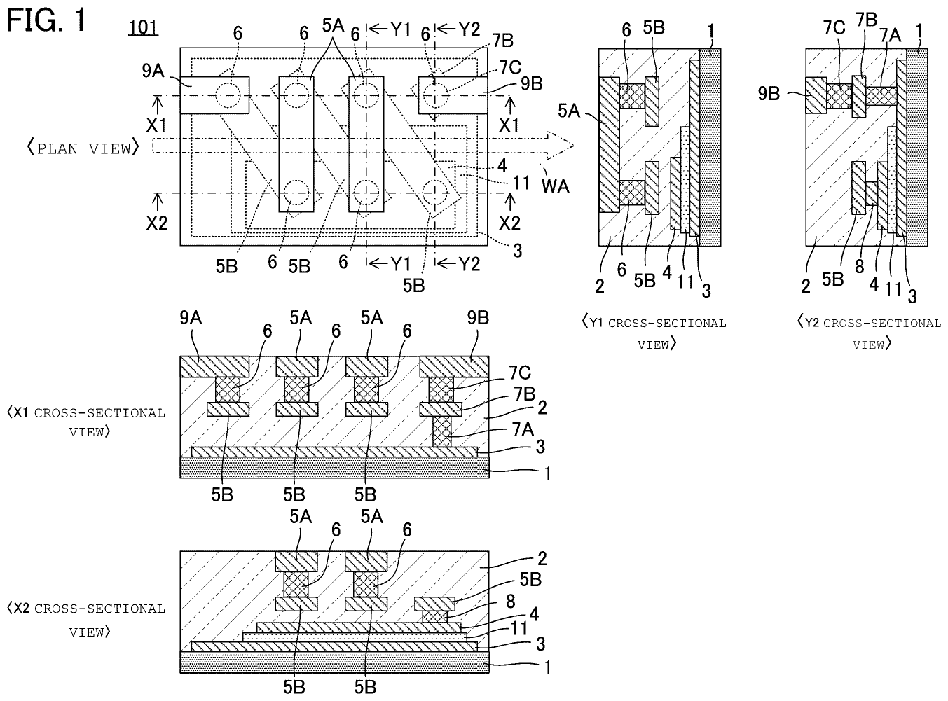

FIG. 1 shows a structure of an electronic component 101 according to a first exemplary embodiment. The <plan view> in FIG. 1 is a plan view of the electronic component 101. The <X1 cross-sectional view> in FIG. 1 is a cross-sectional view taken along a line X1-X1 in the plan view of the electronic component 101, and the <X2 cross-sectional view> in FIG. 1 is a cross-sectional view taken along a line X2-X2 in the plan view of the electronic component 101. In addition, the <Y1 cross-sectional view> in FIG. 1 is a cross-sectional view taken along a line Y1-Y1 in the plan view of the electronic component 101, and the <Y2 cross-sectional view> in FIG. 1 is a cross-sectional view taken along a line Y2-Y2 in the plan view of the electronic component 101.

As shown, the electronic component 101 includes a substrate 1, an insulator layer 2 provided along at least a portion of a surface of the substrate 1, and an inductor provided in the insulator layer 2. In addition, the electronic component 101 includes planar conductor connecting conductors 7A, 7B, and 7C electrically connected to a planar conductor 3 provided on the substrate 1 and extending along the substrate 1, and a planar conductor connecting conductor 8 electrically connected to a planar conductor 4 extending along the substrate 1. For purposes of this disclosure, the planar conductor connecting conductor 7A, 7B, 7C, and 8 corresponds to a “connecting conductor”.

The inductor includes a plurality of surface direction conductors 5A and 5B each extending in a plurality of layers (two layers in this example) along the surface of the substrate 1 (e.g., parallel to the surface of substrate 1), and a plurality of inductor via conductors 6 that connect the surface direction conductors 5A and 5B extending in different layers among the plurality of layers. The inductor is formed as an inductor by a helical coil having a winding axis WA along the surface of the substrate 1. That is, the winding axis WA extends in a direction parallel to the surface of substrate 1.

The planar conductor connecting conductors 7A, 7B, 7C, and 8 are positioned at an end portion (e.g., a coil aperture of a helical coil) in a direction of the winding axis of the helical coil.

In the exemplary aspect, the planar conductors 3 and 4 are configured as capacitor electrodes. In short, the planar conductors 3 and 4, and the dielectric layer 11 interposed between these planar conductors 3 and 4 configure a capacitor.

In such a manner, the planar conductors 3 and 4 are provided at positions closer to the substrate 1 than to the plurality of surface direction conductors 5A and 5B. According to this structure, the inductor by the helical coil configured by the plurality of surface direction conductors 5A and 5B and the plurality of inductor via conductors 6 is positioned near terminal electrodes 9A and 9B. Therefore, a path from a circuit to the inductor is minimized, and the Q value of the inductor is kept high. In addition, the capacitor electrodes are able to be placed so as to overlap in an area in which the coil is provided, which also saves space.

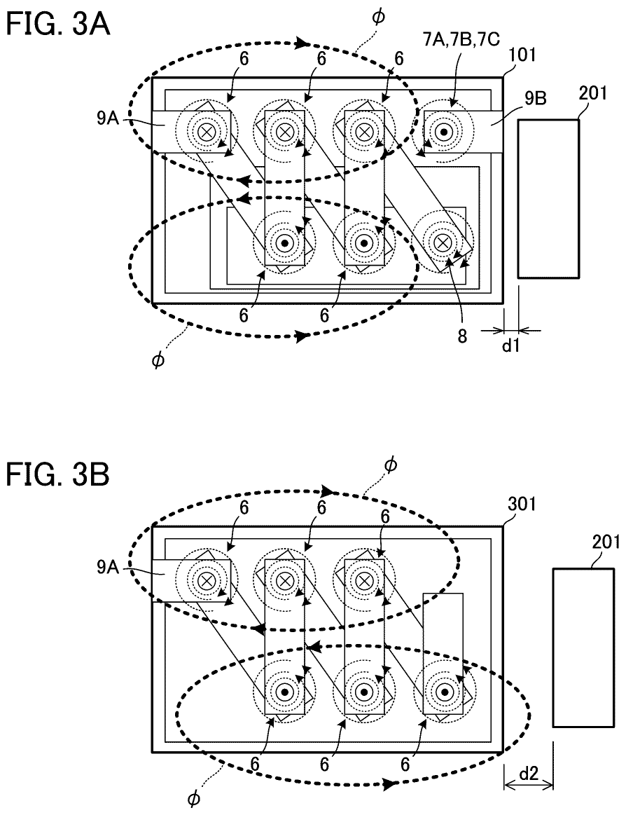

A direction of a current flowing through an inductor via conductor 6 among the plurality of inductor via conductors 6 that is adjacent to the planar conductor connecting conductors 7A, 7B, and 7C and a direction of a current flowing through the planar conductor connecting conductors 7A, 7B, and 7C are opposite to each other. In addition, a direction of a current flowing through an inductor via conductor 6 adjacent to the planar conductor connecting conductor 8 and a direction of a current flowing through the planar conductor connecting conductor 8 are opposite to each other. This will be described below with reference to FIG. 3A, FIG. 3B, and other drawings.

In an exemplary aspect, the substrate 1 is a silicon substrate, for example, and the planar conductor 3 of a thin film such as polysilicon or Al is provided on the surface of this substrate 1. The dielectric layer 11 that can be formed by SiO₂, SiN, or the like, is provided in a predetermined region of an upper surface of the planar conductor 3. The planar conductor 4 of a thin film such as polysilicon or Al is provided on a surface of this dielectric layer 11.

The surface direction conductor 5A and the terminal electrodes 9A and 9B are provided on the surface of the insulator layer 2. The planar conductor 3 is electrically connected to the terminal electrode 9B through the planar conductor connecting conductors 7A, 7B, and 7C. In addition, the planar conductor 4 is electrically connected to the surface direction conductor 5B through the planar conductor connecting conductor 8.

In such a manner, the planar conductor connecting conductor is configured by three portions of the planar conductor connecting conductors 7A, 7B, and 7C. The planar conductor connecting conductor 7B among the planar conductor connecting conductors 7A, 7B, and 7C is provided on the same layer as a layer in which the surface direction conductor 5B is provided. The planar conductor connecting conductor 7B is provided during a step of forming this surface direction conductor 5B. Therefore, a step of forming a special conductor pattern is unnecessary, the special conductor pattern reversing to each other the direction of a current flowing through the inductor via conductor 6 adjacent to the surface direction conductors 5A and 5B among the plurality of inductor via conductors 6 and the direction of a current flowing through the planar conductor connecting conductor 7C.

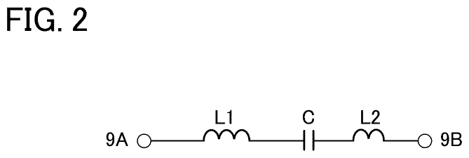

This electronic component 101, as shown in FIG. 2, is configured to function as an LC composite component composed of a series circuit of an inductor and a capacitor. In this electronic component 101, the surface direction conductors 5A and 5B and the inductor via conductor 6 configure a helical coil inductor L1. The planar conductors 3 and 4, and the dielectric layer 11 interposed between these planar conductors 3 and 4 configure a capacitor C. The planar conductor connecting conductors 7A, 7B, 7C, 8, and the like configure an inductor L2.

It is noted that, when the planar conductors 3 and 4 shown in FIG. 1 are resistors, the electronic component 101 is configured to function as an LCR composite component composed of a series circuit of an inductor, a capacitor, and a resistance element.

In such a manner, the electronic component in which the inductor and the capacitor are connected in series can be configured to be used as a frequency filter or an impedance matching circuit.

First, a comparative example of the electronic component 101 is according to the present exemplary embodiment. FIG. 3B is a plan view showing a positional relationship between an electronic component 301 as the comparative example and a member 201 such as a different electronic component adjacent to the electronic component 301. In the electronic component 301 as this comparative example, when a current flows from the terminal electrode 9A, the direction of the magnetic flux around the inductor via conductors 6 at an upper portion in the direction shown in FIG. 3B is the same (e.g., clockwise), and the direction of the magnetic flux around the inductor via conductors 6 at a lower portion is the same (e.g., counterclockwise). Therefore, the entire magnetic flux (i.e., a thick dashed line) o to be generated inside and outside the helical coil expands largely.

On the other hand, FIG. 3A is a plan view showing a positional relationship between the electronic component 101 according to the present exemplary embodiment and a different member 201 adjacent to the electronic component 101. The concentric circle by the dashed line in FIG. 3A shows the magnetic flux to be generated in the inductor via conductor 6, the planar conductor connecting conductor 7C, or the like. The entire magnetic flux φ to be generated inside and outside the helical coil is shown by a thick line.

In the electronic component 101, among the plurality of inductor via conductors 6, the direction of a current flowing through the inductor via conductor (i.e., the inductor via conductor 6 at a right end among the three inductor via conductors 6 at the upper portion in the direction shown in FIG. 3A) adjacent to the planar conductor connecting conductors 7A, 7B, and 7C and the direction of a current flowing through the planar conductor connecting conductors 7A, 7B, and 7C are opposite to each other. Accordingly, in comparison with the example shown in FIG. 3B, the expansion of the magnetic flux φ is significantly reduced. Therefore, even when the member 201 is adjacent to the electronic component 101, the mutual influence is small.

It is noted that, in the electronic component 101 according to the present exemplary embodiment, the direction of a current flowing through the inductor via conductor (i.e., the inductor via conductor 6 at the right end of the two inductor via conductors 6 at the lower portion in the direction shown in FIG. 3A) adjacent to the planar conductor connecting conductor 8 and the direction of a current flowing through the planar conductor connecting conductor 8 are opposite to each other. Therefore, the expansion of the magnetic flux φ can be significantly reduced.

Although the expansion of the magnetic flux φ is large in the electronic component 301 as a comparative example, the expansion of the magnetic flux φ is significantly reduced in the electronic component 101 according to the present exemplary embodiment. This configuration enables a distance d1 between the electronic component 101 and the different member 201 to be smaller than a distance d2 shown in FIG. 3B.

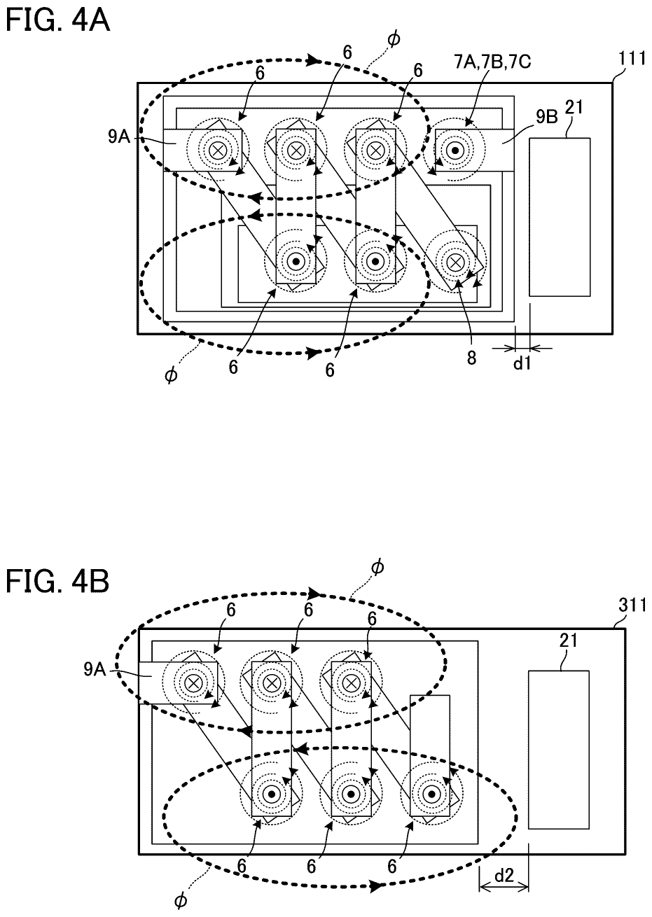

FIG. 4B is a plan view of an electronic component 311 as a comparative example, the electronic component 311 including the helical coil together with a different member 21 in the electronic component. The structure of the helical coil in this electronic component 311 is as shown in FIG. 3B.

On the other hand, FIG. 4A is a plan view of an electronic component 111 according to the present exemplary embodiment. This electronic component 311 includes the different member 21 together with the helical coil in the electronic component. The structure of the helical coil in this electronic component 111 is as shown in FIG. 3A.

Although the expansion of the magnetic flux φ is large in the electronic component 311 as a comparative example, the expansion of the magnetic flux φ is significantly reduced in the electronic component 1 according to the present exemplary embodiment. This configuration enables a distance d1 between the helical coil and the different member 21 to be smaller than the distance d2 of the comparative example, which makes it possible to provide a small electronic component 111.

Although the first exemplary embodiment shows an example in which the inductor via conductors 6 are arranged in two rows, the planar conductor connecting conductors 7A, 7B, and 7C are positioned along with the end portion of one of the two rows of the inductor via conductors 6, and the planar conductor connecting conductor 8 is positioned along with the end portion of the other row, the number of rows of the inductor via conductors 6 is not limited to two in alternative exemplary aspects. In addition, even when the planar conductor connecting conductor 8 is not positioned along with the end portion of all rows, the expansion of the magnetic flux φ can be significantly reduced.

Although, in the example shown in FIG. 3A and FIG. 4A, with respect to the distance between the plurality of inductor via conductors 6, the distance of the end portion of the inductor via conductor 6 and the planar conductor connecting conductors 7A, 7B, and 7C or 8 is equal, this distance is not essential to be equal. However, when this distance is too small, the magnetic fields by the helical coil are weakened by each other, so that the inductance of the inductor by the helical coil is reduced. Conversely, when the distance is too large, the effect of significantly reducing the expansion of the magnetic flux by the helical coil is reduced. Therefore, the distance may be substantially equal.

In the example shown in FIG. 1, the planar conductors 3 and 4, although being provided at the substrate 1, may be provided on an intermediate layer of the insulator layer 2 in an exemplary aspect.

It is noted that a high-frequency magnetic field generated by the helical coil may generate an eddy current in the planar conductors 3 and 4. However, as shown in FIG. 3A, FIG. 3B, FIG. 4A, and FIG. 4B, the expansion of the magnetic flux φ is significantly reduced, loss (e.g., deterioration of the Q value of the inductor) due to the eddy current is significantly reduced.

In addition, in the electronic component shown in the first exemplary embodiment, the planar conductor 3 is provided not only in a portion in which a capacitor is provided, but it is also provided over substantially the entire surface of the substrate 1. Therefore, the electromagnetic shielding property of a member below the substrate 1 or a circuit is also provided.

### Second Exemplary Embodiment

In a second exemplary embodiment, an electronic component different in the configuration of the terminal electrode from the example shown in the first exemplary embodiment will be described.

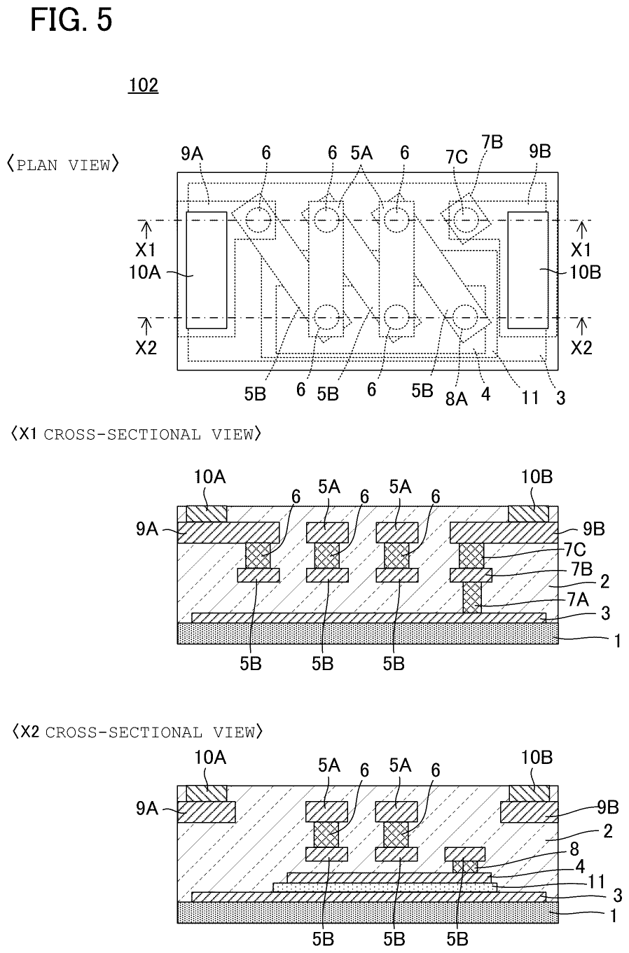

FIG. 5 shows a structure of an electronic component 102 according to the second exemplary embodiment. The <plan view> in FIG. 5 is a plan view of the electronic component 102. The <X1 cross-sectional view> in FIG. 5 is a cross-sectional view taken along a line X1-X1 in the plan view of the electronic component 102, and the <X2 cross-sectional view> in FIG. 5 is a cross-sectional view taken along a line X2-X2 in the plan view of the electronic component 102.

As shown, the electronic component 102 includes a substrate 1, an insulator layer 2 provided along a surface of the substrate 1, an inductor provided in the insulator layer 2, planar conductors 3 and 4 provided on the substrate 1 and extending along the substrate 1, planar conductor connecting conductors 7A, 7B, and 7C electrically connected to the planar conductor 3, and a planar conductor connecting conductor 8 electrically connected to a planar conductor 4.

Terminal electrodes 10A and 10B are provided on the surface of the insulator layer 2. The terminal electrodes 10A and 10B are electrically connected to the terminal electrodes 9A and 9B. Although, in the electronic component 101 shown in the first exemplary embodiment, as shown in FIG. 1, the surface direction conductors 5A and 5B are exposed, together with the terminal electrodes 9A and 9B, only the terminal electrodes 10A and 10B are exposed in the electronic component 102 shown in the second exemplary embodiment. It should be appreciated that other configurations are preferably the same or substantially the same as the configurations shown in the first exemplary embodiment.

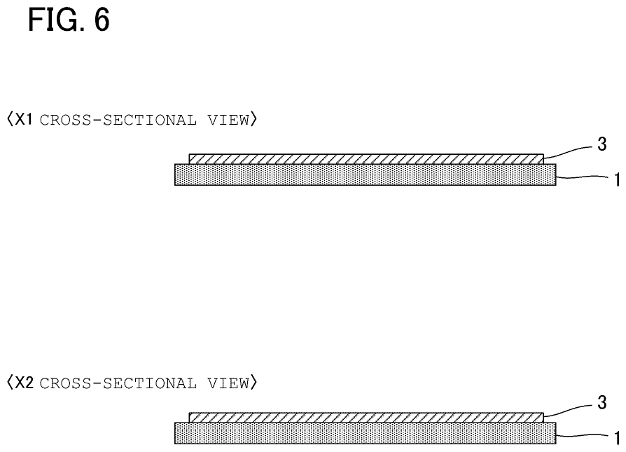

Subsequently, method of manufacturing the electronic component 102 will be described. FIG. 6 is a cross-sectional view in a state in which the planar conductor 3 is provided. The substrate 1 is a silicon intrinsic semiconductor substrate or a silicon impurity semiconductor substrate, and is formed in a semiconductor process such as a process step of vapor-depositing and lifting off an Al film or a Cu film on the surface of the substrate 1, a process step of forming an Al film or a Cu film by sputtering or CVD and performing lithography and etching, or the like.

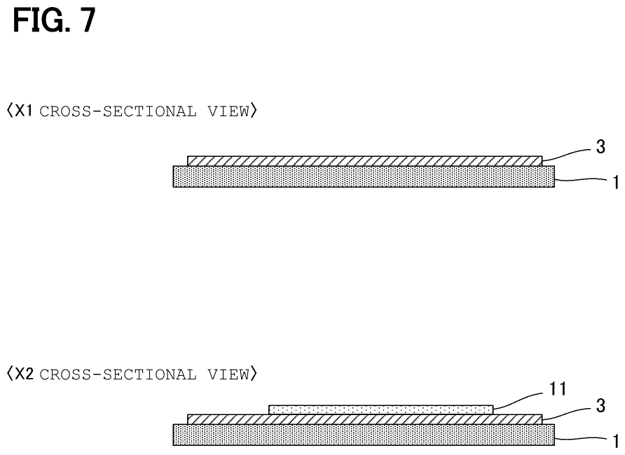

FIG. 7 is a cross-sectional view in a state in which the dielectric layer 11 is provided. In this process step, the dielectric layer 11, such as a SiO₂ film and a SiN film, is formed on a surface of the planar conductor 3 in a semiconductor process such as sputtering or CVD, and, subsequently, a pattern of the dielectric layer 11 is formed by performing lithography and etching.

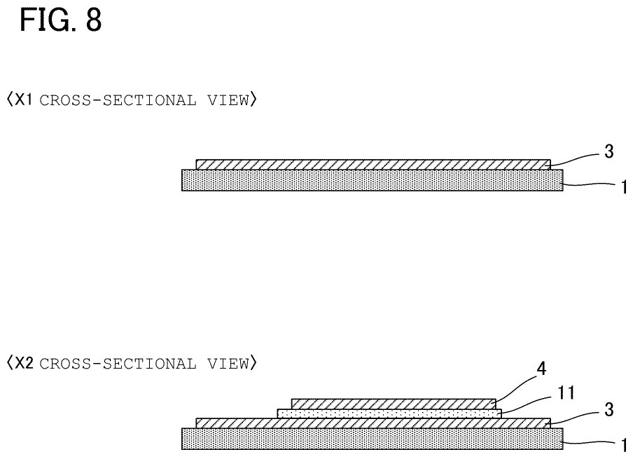

FIG. 8 is a cross-sectional view in a state in which the planar conductor 4 is provided. In this process step, a pattern of the planar conductor 4, similarly to the method of forming the planar conductor 3, is formed in a semiconductor process such as vapor-depositing and lifting off an Al film or a Cu film, forming an Al film or a Cu film by sputtering or CVD and performing lithography and etching, or the like.

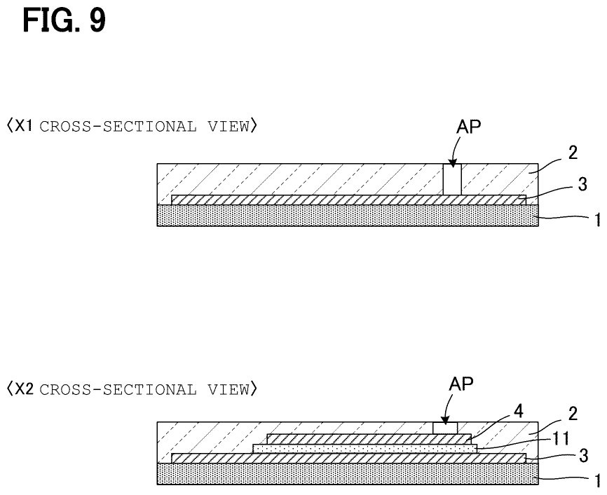

FIG. 9 is a cross-sectional view in a state in which the insulator layer 2 is provided. In this process step, an inorganic film, such as a resin (organic) film, a SiO₂ film, or a SiN film, is formed by a method such as spin coating, CVD, or sputtering, and, subsequently, an aperture AP is formed in a predetermined place by lithography and etching.

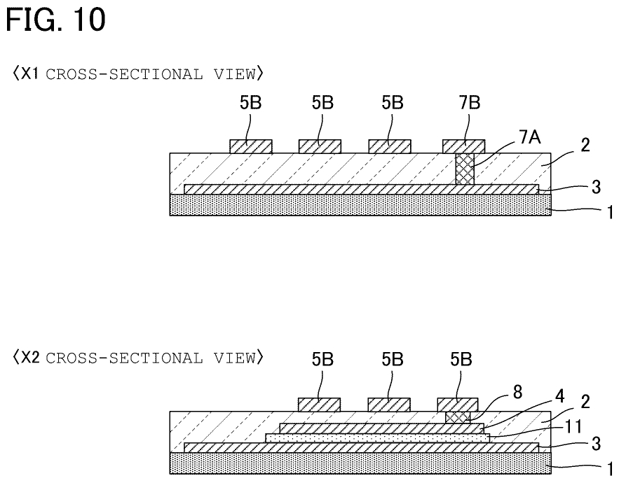

FIG. 10 is a cross-sectional view in a state in which the surface direction conductor 5B and the planar conductor connecting conductor 7B are provided. In this process step, the planar conductor connecting conductors 7A and 8 are formed in the aperture AP shown in FIG. 9, and the surface direction conductor 5B and the planar conductor connecting conductor 7B are formed on the surface of the insulator layer 2. In an exemplary aspect, the conductors are formed by a method such as forming a Cu film and performing lithography the Cu film and plating Cu, or performing sputtering, lithography, and etching Cu, or performing lithography a Cu film, vapor-depositing Cu to the Cu film and liftoff on the Cu film.

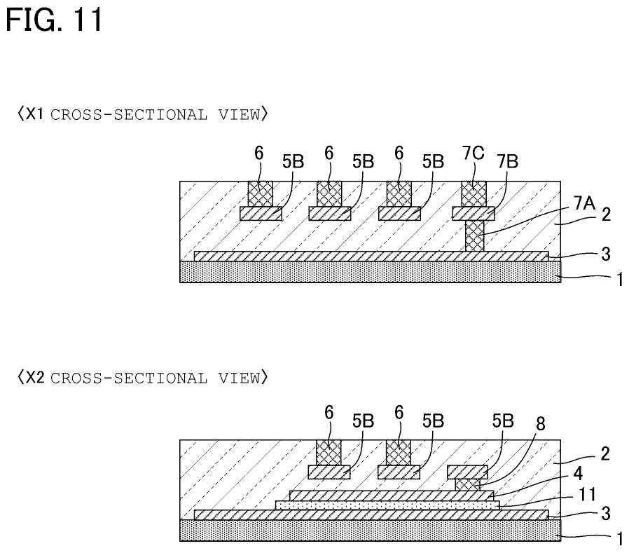

FIG. 11 is a cross-sectional view when the inductor via conductor 6 and the planar conductor connecting conductor 7C are provided. In this process step, a pattern of the planar conductor 4 is formed in a semiconductor process such as vapor-depositing and lifting off an Al film or a Cu film, forming an Al film or a Cu film by sputtering or CVD and performing lithography and etching the Al film or the Cu film, or the like.

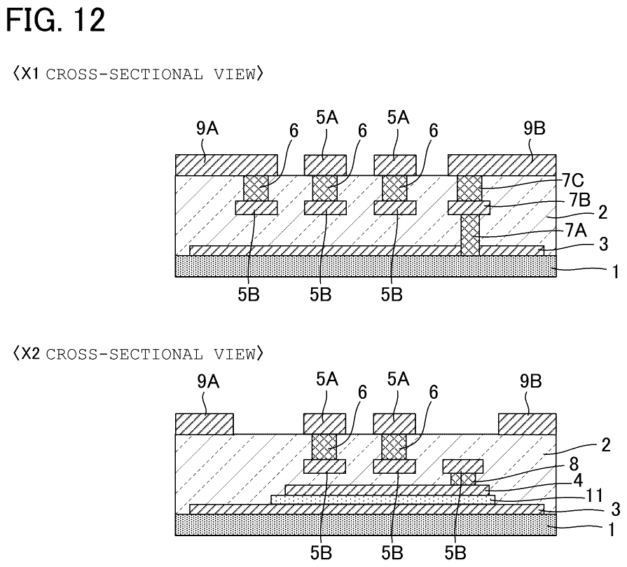

FIG. 12 is a cross-sectional view when the surface direction conductor 5A and the terminal electrodes 9A and 9B are provided. In this process step, the surface direction conductor 5A and the terminal electrodes 9A and 9B are formed on the surface of the insulator layer 2. In an exemplary aspect, the conductor and the terminal electrodes are formed by a method such as forming a Cu film and performing lithography and plating to form the Cu film, or performing sputtering, lithography, and etching Cu, or performing lithography a Cu film, vapor-depositing Cu to the Cu film, and liftoff on the Cu film.

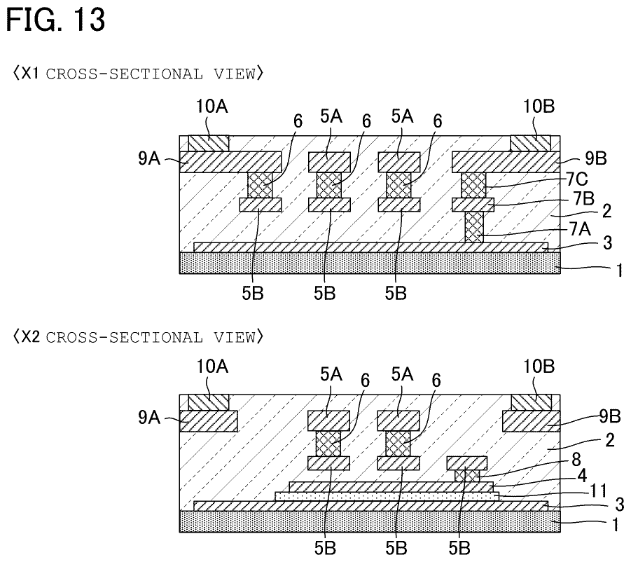

FIG. 13 is a cross-sectional view when the terminal electrodes 10A and 10B are provided. In this process step, the terminal electrodes 10A and 10B are mounting electrodes, and are formed by applying Ni plating, Au plating, or the like on the surface of the terminal electrodes 9A and 9B. Subsequently, a protective film is formed, and portions of the terminal electrode 10A and 10B are opened to expose the terminal electrodes 10A and 10B. The insulator layer 2 may be composed of a plurality of types of layers, and, in a case in which all are formed from the same material, a boundary may not be visible after completion, as shown in FIG. 13.

It is noted that, in this second exemplary embodiment, even when the terminal electrodes 9B and 10B are large, the high-frequency magnetic field generated by the helical coil effectively avoids the terminal electrodes 9B and 10B. Accordingly, the loss due to the eddy current is significantly reduced, and the deterioration of the Q value of the inductor by the helical coil is significantly reduced. The same applies to the other exemplary embodiments to be described below.

### Third Exemplary Embodiment

In a third exemplary embodiment, an electronic component different in the configuration of the planar conductor from the example shown in the first and second exemplary embodiments will be described.

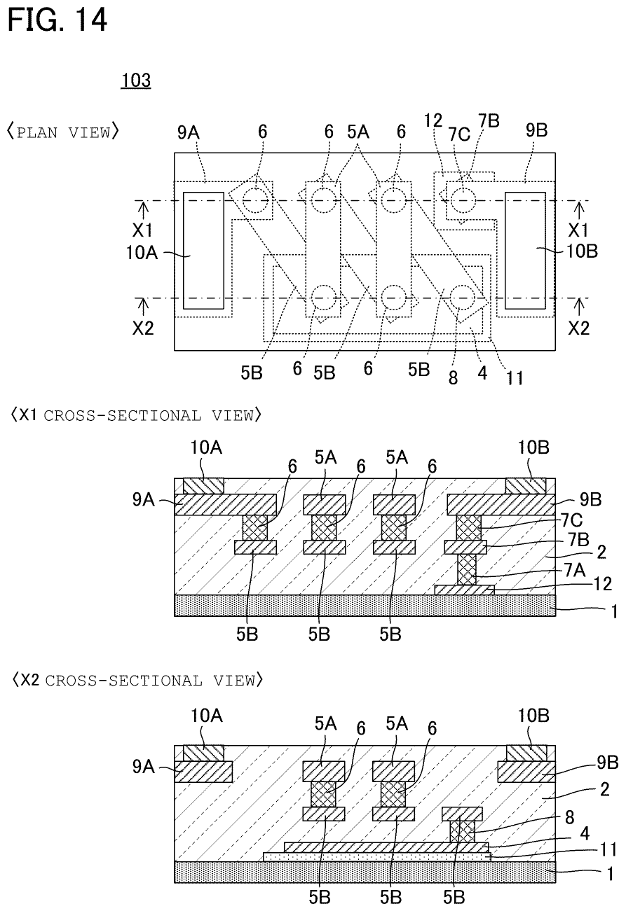

FIG. 14 shows a structure of an electronic component 103 according to the third exemplary embodiment. The <plan view> in FIG. 14 is a plan view of the electronic component 103. The <X1 cross-sectional view> in FIG. 14 is a cross-sectional view taken along a line X1-X1 in the plan view of the electronic component 103, and the <X2 cross-sectional view> in FIG. 14 is a cross-sectional view taken along a line X2-X2 in the plan view of the electronic component 103.

As shown, the electronic component 103 includes a substrate 1, an insulator layer 2 provided along a surface of the substrate 1, an inductor provided in the insulator layer 2, a planar conductor 4 provided on the substrate 1 and extending along the substrate 1, planar conductor connecting conductors 7A, 7B, and 7C electrically connected to the planar conductor 4, and a planar conductor connecting conductor 8 electrically connected to the planar conductor 4.

As further shown in the X2 cross-sectional view, the dielectric layer 11 is provided on the surface of the substrate 1. The planar conductor 4 is provided on the surface of the dielectric layer 11. In addition, as shown in the X1 cross-sectional view, a substrate conduction electrode 12 is formed at a predetermined position on the surface of the substrate 1. According to an exemplary aspect, the substrate 1 is a highly conductive semiconductor substrate, or a semiconductor substrate at which a highly conductive layer is provided on the surface on which each layer is provided. It should be appreciated that other configurations are preferably the same or substantially the same as the configurations shown in the second exemplary embodiment.

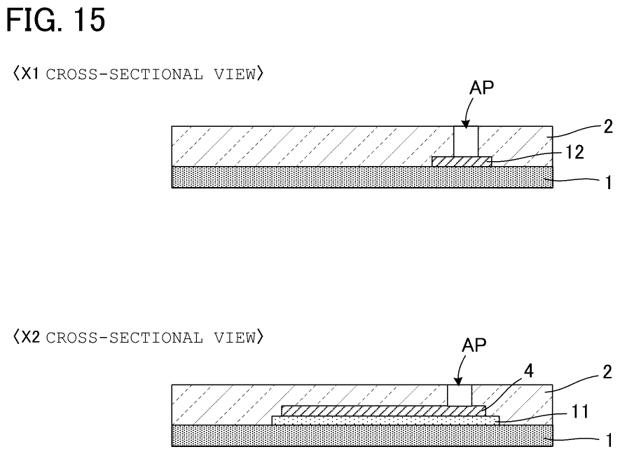

Subsequently, a method of manufacturing the electronic component 103 will be described. FIG. 15 is a cross-sectional view in a state in which a substrate conduction electrode 12, the dielectric layer 11, the planar conductor 4, and the like are provided. In an exemplary aspect, the substrate 1 is a silicon impurity semiconductor substrate, and, in this process step, as shown in the X1 cross-sectional view, is formed in a semiconductor process such as vapor-depositing and lifting off an Al film or a Cu film on the surface of the substrate 1, or forming an Al film or a Cu film by sputtering or CVD and performing lithography and etching, or the like. In addition, as shown in the X2 cross-sectional view, the dielectric layer 11 such as a SiO₂ film and a SiN film is formed on the surface of the substrate 1 in a semiconductor process such as sputtering or CVD, and, subsequently, a pattern of the dielectric layer 11 is formed by performing lithography and etching.

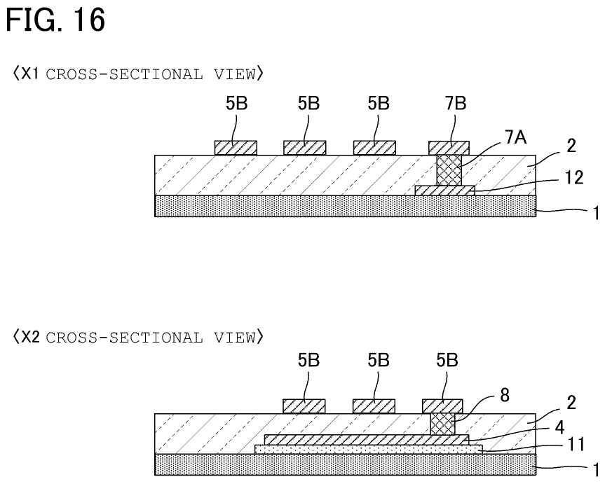

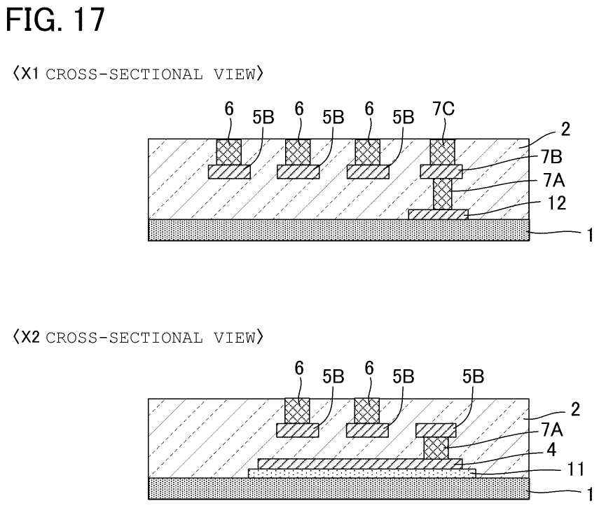

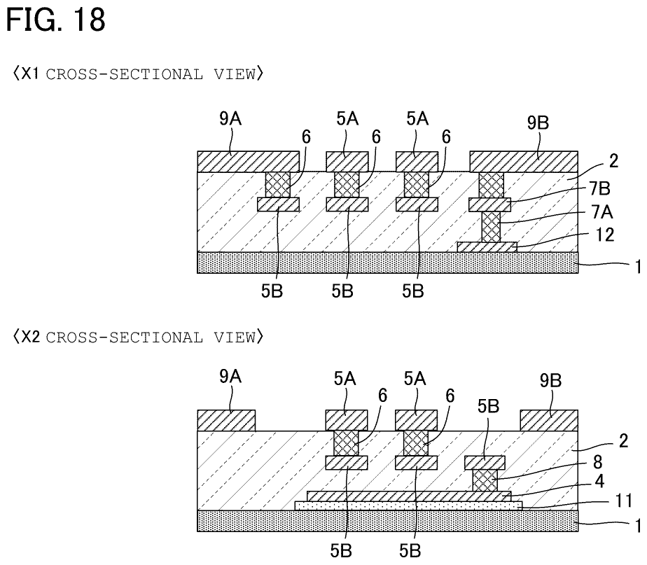

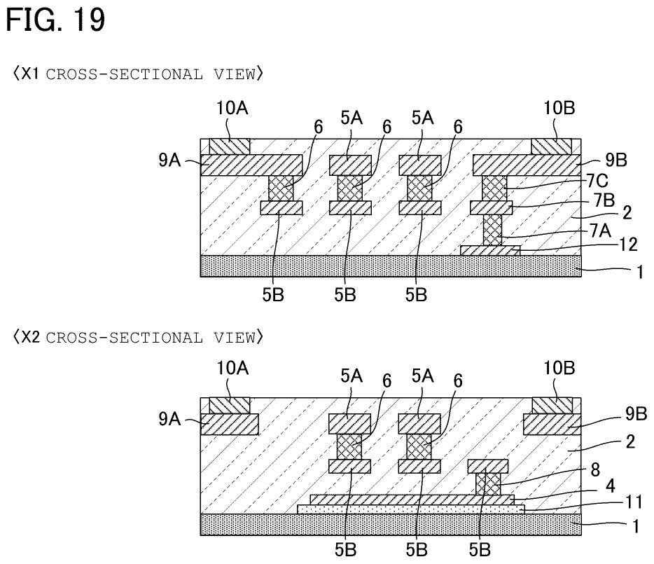

FIG. 16 is a cross-sectional view in a state in which the surface direction conductor 5B and the planar conductor connecting conductor 7B are provided. FIG. 17 is a cross-sectional view in a state in which the inductor via conductor 6 and the planar conductor connecting conductor 7C are provided. FIG. 18 is a cross-sectional view in a state in which the surface direction conductor 5A and the terminal electrodes 9A and 9B are provided. FIG. 19 is a cross-sectional view in a state in which the terminal electrodes 10A and 10B are provided.

It is noted that each process step shown from FIG. 16 to FIG. 19 is preferably the same or substantially the same as each process step shown from FIG. 10 to FIG. 13 in the second exemplary embodiment and will not be repeated in detail herein.

As described above, the present disclosure is also applicable when the substrate is used as a portion of the planar conductor for a capacitor.

### Fourth Exemplary Embodiment

A fourth exemplary embodiment illustrates an electronic component in which the planar conductor configures a semiconductor element, together with a semiconductor substrate.

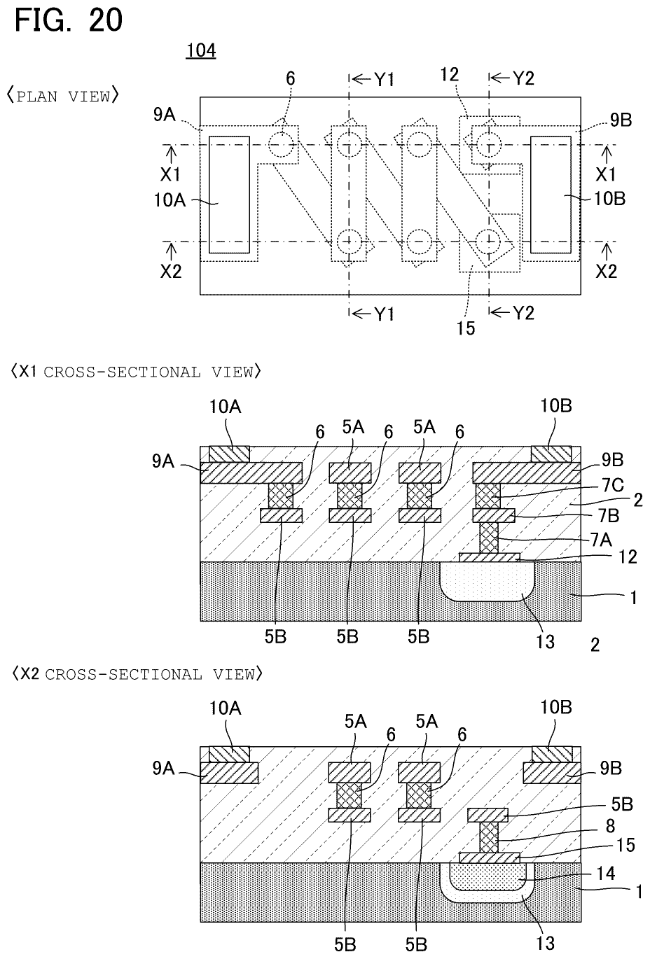

FIG. 20 shows a structure of an electronic component 104 according to the fourth exemplary embodiment. The <plan view> in FIG. 20 is a plan view of the electronic component 104. The <X1 cross-sectional view> in FIG. 20 is a cross-sectional view taken along a line X1-X1 in the plan view of the electronic component 104, and the <X2 cross-sectional view> in FIG. 20 is a cross-sectional view taken along a line X2-X2 in the plan view of the electronic component 104.

In an exemplary aspect, the substrate 1 is a P-type silicon semiconductor substrate, an N-well 13 is provided in a predetermined place of this substrate 1, and a P+ region 14 is provided in a predetermined region in the N-well.

The substrate conduction electrode 12 is provided on a surface of a region of the N-well 13. In addition, a substrate conduction electrode 15 is provided on a surface of the P+ region. According to this structure, the N-well 13, the substrate conduction electrode 12 electrically connected to the N-well 13, the P+ region 14, and the substrate conduction electrode 15 electrically connected to the P+ region 14 configure a diode.

With the above configuration, the electronic component 104 is configured to function as an electronic component in which the diode is connected in series to the inductor by the helical coil. For example, the electronic component 104 can be configured as an ESD protection element.

It is noted that, although the diode is configured on the substrate 1 in the example shown in FIG. 20, a transistor may be similarly configured in an alternative aspect.

Finally, it is noted that the exemplary aspects of the present disclosure are not limited to the foregoing exemplary embodiments. Various modifications or changes can be appropriately made by those skilled in the art. Furthermore, the scope of the present invention is intended to include all possible modifications or changes from the exemplary embodiments.

The configuration of the electronic component of the present disclosure will be described below.
<1> An electronic component is provided that includes a substrate, an insulator layer provided on at least a portion of a surface of the substrate, an inductor in the insulator layer, planar conductors provided on the substrate or in the insulator layer and extending along the substrate, and connecting conductors electrically connected to the planar conductors. In this aspect, the inductor includes a plurality of surface direction conductors each extending in a plurality of layers along the surface of the substrate, and a plurality of inductor via conductors that connect the plurality of surface direction conductors extending in different layers among the plurality of layers. The inductor is thus formed by a helical coil having a winding axis along the surface of the substrate, and a direction of a current flowing through an inductor via conductor among the plurality of inductor via conductors that is adjacent to the connecting conductors and a direction of a current flowing through the connecting conductors are opposite to each other.
<2> In the electronic component according to <1>, the connecting conductors are positioned at an end portion (e.g., a coil aperture of a helical coil inductor) in a direction of the winding axis of the helical coil.
<3> In the electronic component according to <1> or <2>, the planar conductors are provided at positions closer to the substrate than to the plurality of surface direction conductors.
<4> In the electronic component according to <3>, the connecting conductors are each configured by three or more portions, and one of the three or more portions is provided on a same layer as a layer in which the plurality of surface direction conductors are provided.
<5> In the electronic component according to any one of <1> to <4>, the substrate is a semiconductor substrate of a low resistance, and the planar conductors are capacitor electrodes that configure a capacitor, together with the semiconductor substrate.
<6> In the electronic component according to any one of <1> to <5>, the planar conductors are resistor films.
<7> In the electronic component according to any one of <1> to <6>, the substrate is a semiconductor substrate, and the planar conductors configure a semiconductor element, together with the semiconductor substrate.
<8> In the electronic component according to any one of <1> to <7>, the inductor via conductors are arranged in two rows, and the connecting conductors are positioned along with the end portion of the inductor via conductors in the two rows.
<9> In the electronic component according to <8>, the end portion of the inductor via conductors and the connecting conductors are placed at positions at equal intervals.

### REFERENCE SIGNS LIST

AP—aperture
C—capacitor
d—distance
L1—helical coil inductor
L2—inductor
WA—winding axis
1—substrate
2—insulator layer
3, 4—planar conductor
5A, 5B—surface direction conductor
6—inductor via conductor
7A, 7B, 7C, 8—planar conductor connecting conductor
9A, 9B—terminal electrode
10A, 10B—terminal electrode
11—dielectric layer
12—substrate conduction electrode
13—N-well
14—P+ region
15—substrate conduction electrode
21—member
101-104—electronic component
111—electronic component
201—member
301—electronic component as a comparative example
311—electronic component

1. An electronic component comprising:
a substrate;
an insulator layer on at least a portion of a surface of the substrate;
an inductor in the insulator layer, the inductor including:
a plurality of surface direction conductors that extend in a plurality of layers above the surface of the substrate, and
a plurality of inductor via conductors that connect the plurality of surface direction conductors extending in different layers among the plurality of layers, such that the inductor is formed by a helical coil having a winding axis along the surface of the substrate;
one or more planar conductors on the substrate or in the insulator layer and that extend along the substrate; and
one or more connecting conductors electrically connected to the one or more planar conductors,
wherein the inductor is configured such that a direction of a current flowing through an inductor via conductor among the plurality of inductor via conductors that is adjacent to the one or more connecting conductors and a direction of a current flowing through the one or more connecting conductors are opposite to each other.

2. The electronic component according to claim 1, wherein the one or more connecting conductors are positioned at an end portion in a direction of the winding axis of the helical coil.

3. The electronic component according to claim 1, wherein the one or more planar conductors are positioned at positions closer to the substrate than to the plurality of surface direction conductors.

4. The electronic component according to claim 3, wherein the one or more connecting conductors are each configured by three or more portions.

5. The electronic component according to claim 4, wherein one portion of the three or more portions is provided on a same layer as a layer in which the plurality of surface direction conductors are provided.

6. The electronic component according to claim 1, wherein:
the substrate is a semiconductor substrate of a low resistance; and
the one or more planar conductors are capacitor electrodes that configure a capacitor with the semiconductor substrate.

7. The electronic component according to claim 1, wherein the one or more planar conductors are resistor films.

8. The electronic component according to claim 1, wherein:
the substrate is a semiconductor substrate; and
the one or more planar conductors configure a semiconductor element with the semiconductor substrate.

9. The electronic component according to claim 2, wherein the plurality of inductor via conductors are arranged in two rows.

10. The electronic component according to claim 9, wherein the one or more connecting conductors are positioned along with the end portion of the plurality of inductor via conductors in the two rows.

11. The electronic component according to claim 10, wherein the end portion of the plurality of inductor via conductors and the one or more connecting conductors are at positions at equal intervals.

12. The electronic component according to claim 1, wherein the winding axis of the helical coil extends in a direction parallel to the surface of substrate.

13. An electronic component comprising:
a substrate;
an insulator layer on at least a portion of a surface of the substrate;
an inductor in the insulator layer, the inductor including:
a plurality of surface direction conductors that extend in a plurality of layers, and
a plurality of inductor via conductors that connect the plurality of surface direction conductors to provide a helical coil of the inductor that has a winding axis that is parallel to the surface of the substrate;
one or more planar conductors on the substrate or in the insulator layer and that extend parallel to the substrate; and
one or more connecting conductors electrically connected to the one or more planar conductors.

14. The electronic component according to claim 13, wherein the inductor is configured such that a direction of a current flowing through an inductor via conductor among the plurality of inductor via conductors that is adjacent to the one or more connecting conductors and a direction of a current flowing through the one or more connecting conductors are opposite to each other.

15. The electronic component according to claim 13, wherein the one or more connecting conductors are positioned at an end portion in a direction of the winding axis of the helical coil.

16. The electronic component according to claim 13, wherein the one or more planar conductors are positioned at positions closer to the substrate than to the plurality of surface direction conductors.

17. The electronic component according to claim 16, wherein the one or more connecting conductors are each configured by three or more portions, and one portion of the three or more portions is provided on a same layer as a layer in which the plurality of surface direction conductors are provided.

18. The electronic component according to claim 13, wherein:
the substrate is a semiconductor substrate of a low resistance; and
the one or more planar conductors are capacitor electrodes that configure a capacitor with the semiconductor substrate.

19. The electronic component according to claim 13, wherein:
the substrate is a semiconductor substrate; and
the one or more planar conductors configure a semiconductor element with the semiconductor substrate.

20. The electronic component according to claim 15, wherein:
the plurality of inductor via conductors are arranged in two rows, and
the one or more connecting conductors are positioned along with the end portion of the plurality of inductor via conductors in the two rows.
